(19) United States
(12) Patent Application Publication
(10) Pub. No.: US 2024/0090261 A1
(43) Pub. Date: Mar. 14, 2024

(54) DISPLAY DEVICE AND METHOD OF PROVIDING THE SAME

(71) Applicant: Samsung Display Co., LTD., Yongin-si (KR)

(72) Inventors: RAN KIM, Yongin-si (KR); KIHYUN KIM, Yongin-si (KR); YOUNGGIL PARK, Yongin-si (KR)

(21) Appl. No.: 18/189,544

(22) Filed: Mar. 24, 2023

(30) Foreign Application Priority Data
Sep. 13, 2022 (KR) 10-2022-0115099

(51) Int. Cl. H10K 59/121; H10K 59/12; H10K 59/38; H10K 59/80; H10K 71/00

(52) U.S. Cl. CPC H10K 59/1213; H10K 59/1201; H10K 59/38; H10K 59/873; H10K 71/00; H10K 2102/351

(57) ABSTRACT

A display device includes a thin film transistor including an active layer, a gate electrode on the active layer, and an electrode layer having a first stress, the electrode layer including a source electrode and a drain electrode, a light emission layer facing the thin film transistor, and a first passivation layer between the thin film transistor and the light emission layer and covering the thin film transistor, the first passivation layer having a second stress. A difference between an absolute value of the first stress and an absolute value of the second stress is about 600 megapascals or less.

This application claims priority to Korean Patent Application No. 10-2022-0115099 filed on Sep. 13, 2022, and all the benefits accruing therefrom under 35 U.S.C. § 119, the content of which in its entirety is herein incorporated by reference.

### BACKGROUND

### 1. Field

The present disclosure relates to a display device and method of manufacturing (or providing) the same. More particularly, The present disclosure relates to the display device that provides visual information and the method of manufacturing (or providing) the same.

### 2. Description of the Related Art

With a development of information technology, an importance of a display device, which is a connection medium between a user and information, is being highlighted. A use of a display device such as a liquid crystal display device (“LCD”), an organic light-emitting display device (“OLED”), a plasma display device (“PDP”), and the like is increasing.

As the size of the display panel has increased, the size of a mother substrate from which a individual display panel is provided has also increased. Productivity and profitability may be improved as the size of the mother substrate increases.

### SUMMARY

As the size of a mother substrate from which individual display panels are provided increases, the probability of the occurrence of bright spots may increase. Correspondingly, there is a problem that process loss in providing of the individual display panels occurs to eliminate the reliability bright spots.

The present disclosure may provide a display device.

The present disclosure may provide a method of manufacturing (or providing) the display device.

A display device according to embodiments of the present disclosure may include a thin film transistor, a light emission layer, and a first passivation layer. The thin film transistor may include an active layer, a gate electrode, and an electrode layer. The gate electrode may be on the active layer. The electrode layer may have a first stress, and may include a source electrode and a drain electrode. The light emission layer may face the thin film transistor. The first passivation layer may be between the thin film transistor and the light emission layer, may cover the thin film transistor, and may have a second stress. A difference between an absolute value of the first stress and an absolute value of the second stress may be about 600 megapascals (MPa) or less.

In an embodiment, a roughness of the first passivation layer may be about 0.3 nanometer (nm) or more and about 1.1 nanometers (nm) or less.

In an embodiment, the second stress of the first passivation layer may be a compressive stress. The second stress may be about −400 MPa or more and less than about 0 MPa.

In an embodiment, a thickness of the first passivation layer may be about 200 nm or more and about 700 nm or less.

In an embodiment, the display device may further include a second passivation layer including an organic material or an inorganic material. The first passivation layer may be between the thin film transistor and the second passivation layer.

In an embodiment, each of the first passivation layer and the second passivation layer may have surplus unbonded electrons on a surface to define a number of dangling bonds. The number of dangling bonds of the second passivation layer may be smaller than the number of dangling bonds of the first passivation layer.

In an embodiment, each of the first passivation layer and the second passivation layer may include silicon nitride or silicon oxynitride. Each of the silicon nitride and the silicon oxynitride may have a content of nitrogen relative to silicon. The content of nitrogen relative to silicon of the first passivation layer may be greater than the content of nitrogen relative to silicon of the second passivation layer.

In an embodiment, a thickness of the second passivation layer may be about 100 nm or more and about 1000 nm or less.

In an embodiment, within the electrode layer of the thin film transistor, each of the source electrode and the drain electrode may include a first conductive layer, a second conductive layer and a third conductive layer in order toward the first passivation layer. The third conductive layer may include a metal or a metal oxide.

In an embodiment, the first conductive layer may include Ti and the second conductive layer may include Cu.

In an embodiment, the third conductive layer may include at least one among indium tin oxide, titanium, titanium oxide, zinc indium oxide, zinc tin oxide, indium gallium zinc oxide and zinc indium tin oxide.

In an embodiment, the first stress may be defined by the third conductive layer, and may be greater than about 0 MPa and may be about 200 MPa or less.

In an embodiment, each of the source electrode and the drain electrode may further include a capping film. The capping film may be between the second conductive layer and the first conductive layer. The capping film may include a metal or a metal oxide.

In an embodiment, the capping film may include at least one among indium tin oxide, titanium, titanium oxide, zinc indium oxide, zinc tin oxide, indium gallium zinc oxide and zinc indium tin oxide.

In an embodiment, each of the source electrode and the drain electrode may further include a film. The capping film may be between the third conductive layer and the second conductive layer. The capping film may include a metal or a metal oxide.

In an embodiment, the capping film may include at least one among indium tin oxide, titanium, titanium oxide, zinc indium oxide, zinc tin oxide, indium gallium zinc oxide and zinc indium tin oxide.

In an embodiment, the display device may further include an impact-resistance layer and a color filter layer. The impact-resistance layer may be between the first passivation layer and the light emission layer. The color filter layer may be on the light emission layer.

A method of manufacturing (or providing) a display device includes forming (or providing) a thin film transistor including an active layer, a gate electrode on the active layer, an electrode layer having a first stress greater than about 0 MPa and less than about 200 MPa, and the electrode layer including a source electrode and a drain electrode; and providing a first passivation layer on the thin film transistor, the first passivation layer having a second stress. The providing of the first passivation layer includes injecting silane gas and ammonia gas, on the source electrode and the drain electrode, and defining a difference between an absolute value of the first stress and an absolute value of the second stress of about 600 megapascals or less.

In an embodiment, the method may further include after the providing of the first passivation layer, providing a second passivation layer on the first passivation layer, where the providing of the second passivation layer includes injecting hydrogen gas in addition to the silane gas and the ammonia gas, on the source electrode and the drain electrode.

In an embodiment, the method may further include after the providing of the source electrode and the drain electrode, providing a capping film including a metal or a metal oxide, on the source electrode and the drain electrode.

A display device according to embodiments of the present disclosure may include a thin film transistor, a light emission layer, and a first passivation layer. The thin film transistor may include an active layer, a gate electrode, and an electrode layer. The gate electrode may be on the active layer. The electrode layer may have a first stress, and may include a source electrode and a drain electrode. The light emission layer may face the thin film transistor. The first passivation layer may be between the thin film transistor and the light emission layer, may cover the thin film transistor and may have a second stress. A difference between an absolute value of the first stress and an absolute value of the second stress may be about 600 MPa or less. Accordingly, a layer lifting of a bonding interface between the source electrode and the first passivation layer and a bonding interface between the drain electrode and the first passivation layer may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3A is an embodiment of area A of FIG. 2.

FIG. 3B is an embodiment of area A of FIG. 2.

FIG. 4 is an embodiment of area B of FIG. 3A.

FIG. 5 is an embodiment of area B of FIG. 3A.

FIG. 6 is an embodiment of area A of FIG. 2.

FIG. 7 is a flowchart illustrating an embodiment of a method of manufacturing the display device according to an embodiment of the present disclosure.

FIGS. 8, 9, 10, 11, 12, and 13 are cross-sectional views illustrating embodiment of structures within the method of FIG. 7.

### DETAILED DESCRIPTION

Hereinafter, embodiments of the present disclosure will be described in more detail with reference to the accompanying drawings. The same or similar reference numerals are used for the same components in the drawings, and redundant descriptions of the same components will be omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. For example, a reference number labeling a singular form of an element within the figures may be used to reference a plurality of the singular element within the text of the disclosure. As used herein, “a” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

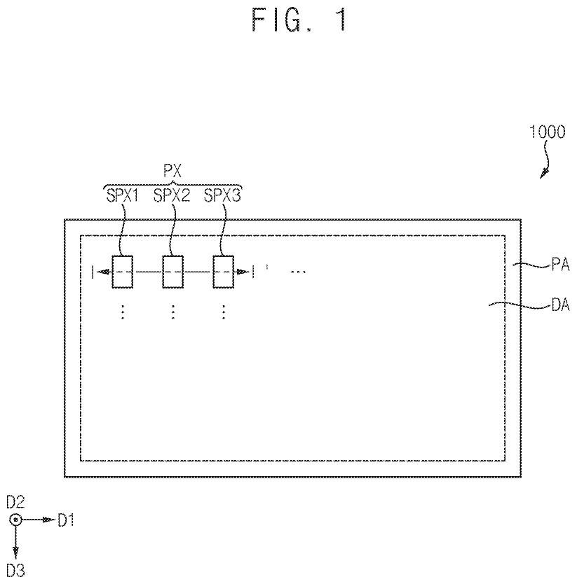

FIG. 1 is a plan view illustrating a display device 1000 according to an embodiment of the present disclosure.

Referring to FIG. 1, a display device 1000 may include a pixel PX provided in plural including a plurality of pixels PX. Each of the pixels PX may be connected to a signal line such as a data line extending in a first direction D1. Each of the pixels PX may also be connected to a signal line such as a scan line extending in a second direction D2 crossing the first direction D1.

Each of the pixels PX may include a plurality of sub-pixels such as sub-pixels SPX1, SPX2, and SPX3. Each of the sub-pixels SPX1, SPX2, and SPX3 may generate and/or emit light of any one color. For example, each of the sub-pixels SPX1, SPX2, and SPX3 may emit light of any one color among red, green, and blue. However, the present disclosure is not limited thereto, and each of the sub-pixels SPX1, SPX2, and SPX3 may emit light of various colors.

A display area DA may be defined as an area (e.g., a planar area within a plane defined by the first direction D1 and the second direction D2 crossing each other) in which an image is provided through or by light emitted by the pixels PX. The image may be displayed in a third direction D3 crossing the plane formed by the first direction D1 and the second direction D2 intersecting each other. The third direction D3 may be referred to as a front direction or a thickness direction. The third direction D3 may be a direction normal or perpendicular to the D1-D2 plane, without being limited thereto.

A non-display area PA may be disposed adjacent to or outside the display area DA. That is, the non-display area PA may surround the display area DA on the plane formed (or provided) by the first direction D1 and the second direction D2. The non-display area PA may be an area in which the pixels PX may not be disposed. That is, the non-display area PA may not provide the image. In the non-display area PA, driving signal lines or control signal lines such as power voltage wires capable of applying different power voltages may be disposed. Also, in the non-display area PA, a scan driver providing a scan signal as an electrical signal to the scan line connected to each of the pixels PX, and a data driver providing a data signal as an electrical signal to the data line connected to each pixel PX may be disposed.

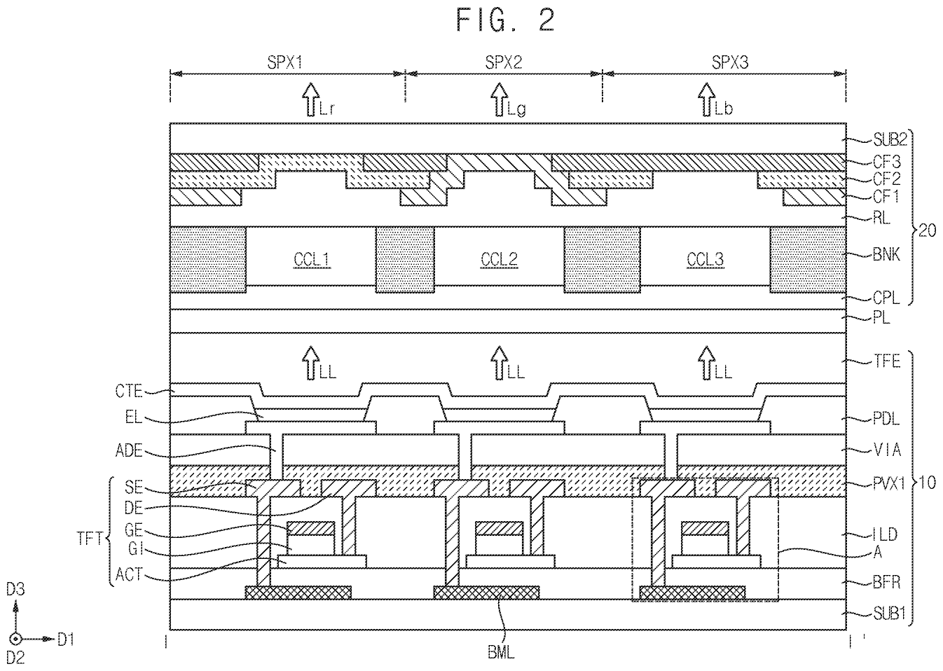

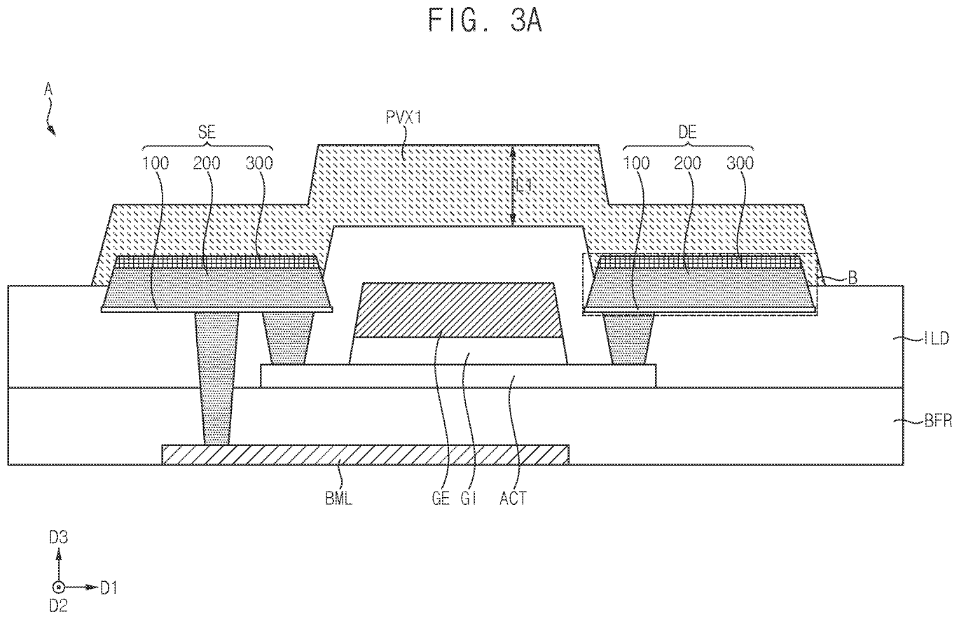

FIG. 2 is a cross-sectional view taken along line I-I′ of FIG. 1, FIG. 3A is an embodiment of area A of FIG. 2, and FIG. 3B is an embodiment of area A of FIG. 2.

Referring to FIGS. 2, 3A and 3B, the display device 1000 according to embodiments of the present disclosure may include a first substrate SUB1, a metal layer BML, a buffer layer BFR, a thin film transistor TFT of a pixel circuit layer, a first passivation layer PVX1, a via insulating layer VIA, a pixel electrode ADE of a light emitting element in a display element layer, a pixel defining layer PDL, a light emitting layer EL as a light emitting pattern of the display element layer, an upper electrode CTE of the light emitting element in the display element layer, an encapsulation layer TFE, a filling layer PL, a capping layer CPL, a barrier structure BNK within a bank layer, color conversion layers CCL1, CCL2, and CCL3 as color conversion patterns within a color-converting layer, a low refractive index layer RL, color filter layers CF1, CF2, and CF3 as color filter patterns within a color filter layer, and a second substrate SUB2.

The thin film transistor TFT may be disposed on the buffer layer BFR. The thin film transistor TFT may include an active layer ACT, a gate insulating layer GI as a gate insulating pattern of a first insulating layer, a gate electrode GE, an interlayer insulating layer ILD as an interlayer insulating pattern of a second insulating layer, a source electrode SE, and a drain electrode DE. The arrangement order of the following components is not limited thereto.

The first substrate SUB1 may include a glass substrate, a quartz substrate, a plastic substrate, and the like.

For example, when the first substrate SUB1 includes the plastic substrate, the first substrate SUB1 may include polyethersulphone (PES), polyacrylate (PAR), polyetherimide (PEI), polyethylene naphthalate (PEN), polyethylene terephthalate (PET), polyphenylene sulfide (PPS), polyarylate (PAR), polyimide (PI), polycarbonate (PC), cellulose acetate propionate (CAP), and the like. These may be used alone or in combination with each other.

The first substrate SUB1 may have a single-layer structure (e.g., a monolayer). Optionally, the first substrate SUB1 may have a multi-layer structure. The multi-layer structure may include two layers and a barrier layer disposed between the two layers. The two layers may include the polymer resin and the barrier layer may include an inorganic material. For example, the barrier layer may include silicon oxide (SiOx), silicon nitride (SiNx), silicon oxynitride (SiOxNy), and the like. These may be used alone or in combination with each other.

The metal layer BML may be disposed on the first substrate SUB1.

The metal layer BML may include metals, alloys, metal nitrides, conductive metal oxides, transparent conductive materials, and the like. The metal layer BML may include gold (Au), silver (Ag), aluminum (Al), tungsten (W), copper (Cu), platinum (Pt), nickel (Ni), titanium (Ti), palladium (Pd), magnesium (Mg), calcium (Ca), lithium (Li), chromium (Cr), tantalum (Ta), molybdenum (Mo), scandium (Sc), neodymium (Nd), iridium (Ir), alloys including aluminum, aluminum nitride (AlN), alloys including silver, tungsten nitride (WN), alloys including copper, alloys including molybdenum, titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), and the like. These may be used alone or in combination with each other.

In an embodiment, the metal layer BML may have a multi-layer structure including a plurality of metal layers arranged along the thickness direction. For example, the plurality of metal layers may have different thicknesses or may include different materials.

The metal layer BML may prevent the active layer ACT from degrading due to light exposure of the active layer ACT. In addition, the metal layer BML may be connected to other wires (e.g., other signal wires, conductive wires, driving (or control) signal wires, etc.) to receive a constant voltage or the like.

The buffer layer BFR may be disposed on the metal layer BML.

The buffer layer BFR may include inorganic materials such as a silicon material or a metal oxide. The buffer layer BFR may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), and the like. These may be used alone or in combination with each other.

The buffer layer BFR may have a single-layer structure. Optionally, the buffer layer BFR may have a multi-layer structure including a plurality of insulating layers.

The buffer layer BFR may prevent impurities such as oxygen and moisture from spreading to the top of the first substrate SUB1.

The active layer ACT may be disposed on the buffer layer BFR. The active layer ACT may overlap the metal layer BML.

In one embodiment, the active layer ACT may include a silicon semiconductor. Examples of the silicon semiconductor may include amorphous silicon, polycrystalline silicon, and the like. These may be used alone or in combination with each other.

In an embodiment, the active layer ACT may include an oxide semiconductor. Examples of the oxide semiconductor may include oxides of zinc, indium, gallium, tin, titanium, phosphorus, and the like. These may be used alone or in combination with each other. For example, the oxide semiconductor may include zinc oxide, zinc-tin oxide, zinc-indium oxide, indium oxide, titanium oxide, indium-gallium-zinc oxide, and indium-zinc-tin oxide, and the like. These may be used alone or in combination with each other.

The active layer ACT may include a channel region, a source region, and a drain region. The channel region may be positioned between the source region and the drain region in a direction along a respective layer or a respective substrate, and may be a region not doped with impurities. The source region and the drain region may be a region doped with the impurities.

The gate insulating layer GI may be disposed on the active layer ACT. The gate insulating layer GI may overlap (or correspond to) the channel region of the active layer ACT.

In one embodiment, the gate insulating layer GI may include a silicon material. Examples of the silicon material may include silicon oxide (SiOx), silicon nitride (SiNx), silicon carbide (SiCx), silicon oxycarbide (SiOxCy), silicon oxynitride (SiOxNy), silicon carbonitride (SiCxNy), and the like. These may be used alone or in combination with each other.

In an embodiment, the gate insulating layer GI may include a metal oxide. Examples of the metal oxide may include aluminum oxide (AlO), aluminum nitride (AlN), tantalum oxide (TaO), hafnium oxide (HfO), zirconium oxide (ZrO), titanium oxide (TiO), and the like. These may be used alone or in combination with each other.

The gate insulating layer GI may have a single-layer structure. Optionally, the gate insulating layer GI may have a multi-layer structure including a plurality of insulating layers. For example, the plurality of insulating layers may have different thicknesses or may include different materials.

The gate electrode GE may be disposed on the gate insulating layer GI. The gate electrode GE may overlap the channel region of the active layer ACT.

The gate electrode GE may include a metal, an alloy, a metal nitride, a conductive metal oxide, a transparent conductive material, and the like. These may be used alone or in combination with each other. For example, the gate electrode GE may include molybdenum (Mo), aluminum (Al), titanium (Ti), copper (Cu), and the like. These may be used alone or in combination with each other.

The gate electrode GE may receive a signal (e.g., an electrical) to turn on and off the thin film transistor TFT. That is, the gate electrode GE may receive a gate signal as the electrical signal).

The interlayer insulating layer ILD may be disposed on the buffer layer BFR and the gate electrode GE. The interlayer insulating layer ILD may be entirely disposed in the display area DA and the non-display area PA. That is, a layer may be disposed corresponding to an entirety of the display area DA and the non-display area PA, except for holes or openings defined in the layer. The interlayer insulating layer ILD may sufficiently cover the active layer ACT and the gate electrode GE, on the buffer layer BFR.

The interlayer insulating layer ILD may include a silicon material, a metal oxide, and the like. These may be used alone or in combination with each other.

The interlayer insulating layer ILD may have a single-layer structure. Optionally, the interlayer insulating layer ILD may have a multi-layer structure including a plurality of insulating layers. For example, the plurality of insulating layers may have different thicknesses or may include different materials.

The source electrode SE and the drain electrode DE may be disposed on the gate electrode GE.

Each of the source electrode SE and the drain electrode DE may include a metal, an alloy, a metal nitride, a conductive metal oxide, a transparent conductive material, and the like. These may be used alone or in combination with each other.

Each of the source electrode SE and the drain electrode DE may contact the active layer ACT at or through a contact hole defined extended through the interlayer insulating layer ILD and the gate insulating layer GI. As being in contact, elements may form an interface therebetween, without being limited thereto. The source electrode SE may receive a signal and transfer the signal to the gate electrode GE, and the drain electrode DE may transfer the signal to the metal layer BML.

The first passivation layer PVX1 may be disposed on the thin film transistor TFT. That is, the first passivation layer PVX1 may cover the thin film transistor TFT. The first passivation layer PVX1 may be entirely disposed in the display area DA and the non-display area PA. The first passivation layer PVX1 may cover the source electrode SE and the drain electrode DE. That is, the first passivation layer PVX1 may protect the source electrode SE and the drain electrode DE.

As shown in FIG. 3A, the first passivation layer PVX1 may be patterned, such as to define a first passivation layer pattern. As used herein, a pattern may have a discrete planar shape, without being limited thereto. Optionally, as shown in FIG. 3B, the first passivation layer PVX1 may be formed on an entirety of the underlying surface, such as to be continuous across pixels PX. Below, FIG. 3A is described as an example, but the present disclosure is not limited thereto.

In an embodiment, a thickness L1 (e.g., a first thickness) of the first passivation layer PVX1 may be about 200 nanometers (nm) or more and about 700 nm or less. Herein, a thickness may be defined from a reference such as a surface. Various thicknesses may be defined along an underlying layer, at positions along the underlying layer. Herein, a thickness range may indicate a maximum thickness of an element or layer, without being limited thereto.

When the thickness L1 of the first passivation layer PVX1 is less than about 200 nm, the first passivation layer PVX1 may be vulnerable to cracks and the like. Therefore, elements disposed under the first passivation layer PVX1 may not be protected from moisture or foreign substances.

When the thickness L1 of the first passivation layer PVX1 exceeds about 700 nm, the characteristics of the elements may change, and the change may be disadvantageous to implement a flexible display.

The via insulating layer VIA may be disposed on the first passivation layer PVX1.

The via insulating layer VIA may include an inorganic insulating material or an organic insulating material. In one embodiment, the via insulating layer VIA may include the organic insulating material. The via insulating layer VIA may include photoresist, polyacryl-based resin, polyimide-based resin, polyamide-based resin, siloxane-based resin, acrylic-based resin, epoxy-based resin, and the like. These may be used alone or in combination with each other.

The pixel electrode ADE of a light emitting element in the display element layer may be disposed on the via insulating layer VIA.

The pixel electrode ADE may include a conductive material such as a metal, an alloy, a conductive metal nitride, a conductive metal oxide, a transparent conductive material, and the like. These may be used alone or in combination with each other.

The pixel electrode ADE may have a single-layer structure. Optionally, the pixel electrode ADE may have a multi-layer structure including a plurality of conductive layers.

The pixel electrode ADE as a lower electrode may be electrically connected to the thin film transistor TFT through a contact hole passing through the first passivation layer PVX1 and the via insulating layer VIA. For example, the pixel electrode ADE may be an anode electrode.

The pixel defining layer PDL may be disposed on the pixel electrode ADE.

The pixel defining layer PDL may include an organic material. In an embodiment, the pixel defining layer PDL may include photoresist, polyacryl-based resin, polyimide-based resin, or polyamide-based resin, siloxane-based resin, acrylic-based resin, epoxy-based resin, and the like. These may be used alone or in combination with each other.

The pixel defining layer PDL may define a pixel opening exposing the pixel electrode ADE to outside the pixel defining layer PDL. Solid portions of the pixel defining layer PDL may define a gap therebetween corresponding to the pixel opening.

The light emitting layer EL may be disposed on an exposed portion of the pixel electrode ADE which is exposed to outside the pixel defining layer PDL by (or at) the pixel opening.

The light emitting layer EL may include organic light emitting materials, quantum dots, and the like. These may be used alone or in combination with each other. In one embodiment, the light emitting layer EL may generate blue light. In an embodiment, the light emitting layer EL may generate red light, green light, or lights having different colors from each other.

The light emitting layer EL may have a multi-layer structure. In one embodiment, the light emitting layer EL may have the multi-layer structure in which blue organic light emitting layers are stacked. In an embodiment, the light emitting layer EL may have the multi-layer structure in which organic light emitting layers emitting lights having different colors are stacked.

Functional layers of the light emitting element may be disposed upper and/or lower part the light emitting layer EL. For example, the functional layers may include a hole injection layer, a hole transport layer, an electron transport layer, an electron injection layer, and the like.

Incident light LL may be emitted from the light emitting layer EL. In one embodiment, the incident light LL emitted from the light emitting layer EL may be blue light. Since light is emitted from the display element layer including the light emitting layer EL, the display element layer may be considered as a light emission layer. A portion of the blue light may be converted into red light and green light while passing through the upper substrate 20. A detailed description of the upper substrate 20 will be described later in the filling layer PL.

The upper electrode CTE of the light emitting element may be disposed on the light emitting layer EL.

The upper electrode CTE may include a metal, an alloy, a conductive metal nitride, a conductive metal oxide, a transparent conductive material, and the like. These may be used alone or in combination with each other.

The upper electrode CTE may have a single-layer structure. Optionally, the upper electrode CTE may have a multi-layer structure including a plurality of conductive layers. For example, the upper electrode CTE may be a cathode electrode.

The encapsulation layer TFE may be disposed on the upper electrode CTE of the display element layer.

In one embodiment, the encapsulation layer TFE may include at least one inorganic encapsulation layer and at least one organic encapsulation layer. For example, the encapsulation layer TFE may include a first inorganic encapsulation layer disposed on the upper electrode CTE, an organic encapsulation layer disposed on the first inorganic encapsulation layer, and a second inorganic encapsulation layer disposed on the organic encapsulation layer.

In an embodiment, the encapsulation layer TFE may include only inorganic encapsulation layers. For example, the encapsulation layer TFE may include a first inorganic encapsulation layer disposed on the upper electrode CTE, and a plasma-treated second inorganic encapsulation layer disposed on the first inorganic encapsulation layer.

The filling layer PL may be disposed on the encapsulation layer TFE. A configuration of layers up to and including the encapsulation layer TFE which are stacked on the first substrate SUB1 along the third direction D3, may together define the lower substrate 10. The lower substrate 10 may include the display element layer and the pixel circuit layer which is connected to the display element layer, without being limited thereto.

A configuration of layers from the filling layer PL, up to and including the capping layer CPL which are stacked along the third direction D3 on the second substrate SUB2 to be described later, may defined as the upper substrate 20. The upper substrate 20 and the lower substrate 10 may be bonded after each process in a method of manufacturing or providing the display device 1000. The filling layer PL may maintain the gap between the lower substrate 10 and the upper substrate 20. That is, the filling layer PL may act as a buffer against external pressure and the like applied to the display device 1000. The filling layer PL may be otherwise referred to as an impact-resistance layer.

The capping layer CPL may be disposed on the filling layer PL. In one embodiment, the capping layer CPL may include a silicon material or the like.

The barrier structure BNK may be disposed on the capping layer CPL.

In one embodiment, the barrier structure BNK may include an organic material or the like. In detail, the barrier structure BNK may include the organic material including a light blocking material. For example, the light blocking material may include a black pigment, dye, carbon black, and the like. These may be used alone or in combination with each other.

A plurality of openings may be formed in or by solid material portions of the barrier structure BNK which are spaced apart from each other. The barrier structure BNK may form a space (e.g., gap, groove, etc.) capable of accommodating an ink composition for forming a first color conversion layer CCL1, a second color conversion layer CCL2, and a transmission layer CCL3 of the color-converting layer. For example, the barrier structure BNK may have a grid shape or a matrix shape in a plan view (e.g., a view of the D1-D2 plane). In one embodiment, the barrier structure BNK may include an organic material.

The color conversion layers CCL1, CCL2, and CCL3 may be disposed on the barrier structure BNK. The color conversion layers CCL1, CCL2, and CCL3 of the color-converting layer and the barrier structure BNK of the bank layer may be coplanar with each other in a same layer. The color conversion layers CCL1, CCL2, and CCL3 together with the barrier structure BNK may define a color-control layer. Since light is emitted from the color-control layer, the color-control layer may be considered as a light emission layer.

The color conversion layers CCL1, CCL2, and CCL3 may include the first color conversion layer CCL1, the second color conversion layer CCL2, and the transmission layer CCL3 disposed apart from each other (e.g., spaced apart from each other along the lower substrate 10. The first color conversion layer CCL1, the second color conversion layer CCL2, and the transmission layer CCL3 may be respectively disposed in the openings of the barrier structure BNK.

In an embodiment, each of the first color conversion layer CCL1 and the second color conversion layer CCL2 may include a resin part, a scatterer (e.g., a light scatterer), and a color conversion particle.

The scatterer may increase the light path of light by scattering the incident light LL without substantially changing the wavelength of the incident light LL incident on the first color conversion layer CCL1 and the second color conversion layer CCL2. The scatterer may include a metal oxide, an organic material, and the like. Optionally, the scatterer may be omitted.

The color conversion particle may include quantum dot. The quantum dot may be defined as semiconductor particle having nanocrystals. The quantum dot may have a specific band gap depending on a composition and size of the quantum dot. Accordingly, the quantum dot may absorb incident light LL having a wavelength and emit light having a different wavelength from the incident light LL (e.g., to wavelength-convert the incident light LL). In one embodiment, the quantum dot may emit red light by absorbing incident light LL. In an embodiment, the quantum dot may emit green light by absorbing incident light LL. For example, the quantum dot may have a diameter of about 100 nm or less. In an embodiment, the quantum dot may have the diameter of about 1 nm to about 20 nm.

The scatterer and the color conversion particle may be disposed in the resin part. The resin part may include an epoxy-based resin, an acrylic-based resin, a phenol-based resin, a melamine-based resin, a cardo-based resin, an imide-based resin, and the like. These may be used alone or in combination with each other.

The incident light LL may be converted into first transmitted light Lr while passing through the first color conversion layer CCL1, and the incident light LL not converted by the first color conversion layer CCL1 may be blocked in the color filter layers CF1, CF2, CF3 to be described later. The incident light LL may be converted into second transmitted light Lg while passing through the second color conversion layer CCL2, and the incident light LL not converted by the second color conversion layer CCL2 may be blocked in the color filter layers CF1, CF2, and CF3 to be described later.

The transmission layer CCL3 may transmit and emit the incident light LL without wavelength-conversion or color-conversion.

The transmission layer CCL3 may include the resin part and a scatterer. The resin part and a scatterer of the transmission layer CCL3 may be substantially the same as or similar to the resin part and a scatterer included in the first color conversion layer CCL1 and the second color conversion layer CCL2. However, the present disclosure is not limited thereto, and the transmission layer CCL3 may convert the incident light LL into third transmitted light Lb having a blue color. At this time, the transmission layer CCL3 may further include the color conversion particle including the quantum dot that absorb incident light LL and emit blue light. Some of the incidents light LL may be blocked by a third color filter CF3 to be described later.

As the first to third transmitted lights Lr, Lg, and Lb are combined, the image may be displayed in the display area DA.

The low refractive index layer RL may be disposed on the color conversion layers CCL1, CCL2, and CCL3. A refractive index of the low refractive layer index layer RL may be smaller than a refractive index of the color conversion layers CCL1, CCL2, and CCL3.

In one embodiment, the low refractive index layer RL may include an organic material and/or an inorganic material. For example, the low refractive index layer RL may include fluorinated-polysiloxane, fluorinated-polyurethane, fluorinated-polyurethane-acrylate, fluorinated polyhedral oligomer silsesquioxane. -polyhedral oligomeric silsesquioxane) or the like. These may be used alone or in combination with each other. The low refractive index layer RL may further include inorganic particles having hollows defined therein. For example, the low refractive index layer RL may further include silica (SiO2), magnesium fluoride (MgF2), iron oxide (Fe3O4), or the like. These may be used alone or in combination with each other.

The low refractive index layer RL may control a path of light emitted from the lower part of the stacked structure within the display device 1000. For example, the low refractive index layer RL may change the path of obliquely incident light to travel in a front direction (e.g., in the third direction D3). Accordingly, the low refractive index layer RL may increase luminous efficiency of the display device 1000.

The color filter layers CF1, CF2, and CF3 may be disposed on the low refractive index layer RL.

The color filter layers CF1, CF2, and CF3 may include a first color filter CF1, a second color filter CF2, and the third color filter CF3.

In one embodiment, the first color filter CF1 may be a red color filter. The red color filter may selectively transmit the red light. The second color filter CF2 may be a green color filter. The green color filter may selectively transmit the green light. The third color filter CF3 may be a blue color filter. The blue color filter may selectively transmit the blue light.

The second substrate SUB2 may be disposed on the color filter layers CF1, CF2, and CF3. The second substrate SUB2 may be disposed to face the first substrate SUB1.

The second substrate SUB2 may be an insulating substrate including a transparent material. For example, the second substrate SUB2 may include glass or plastic.

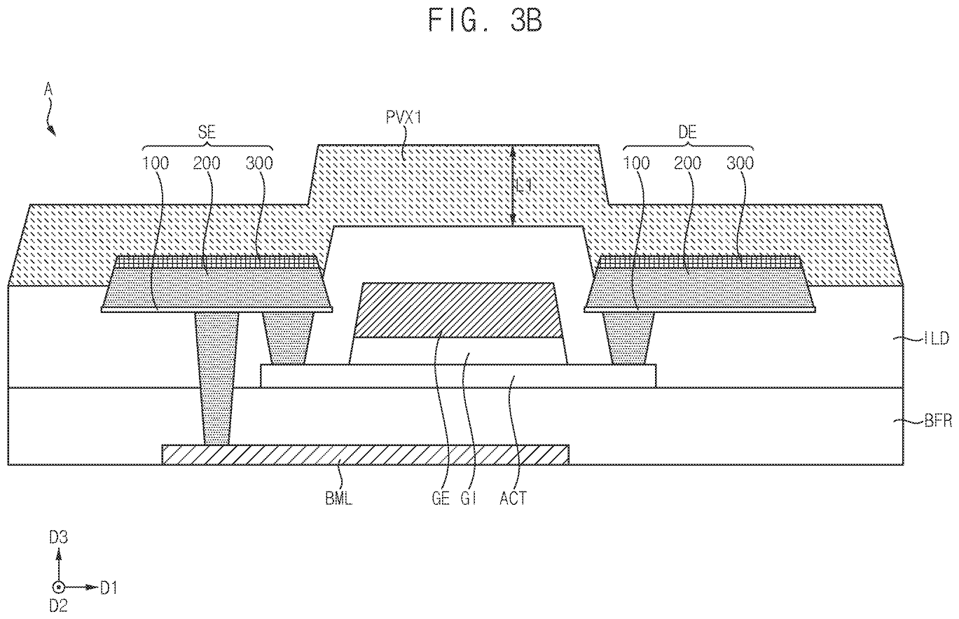

FIG. 4 is an embodiment of area B of FIG. 3A.

The area B is an enlarged view of an electrode of the thin film transistor TFT. Referring to FIGS. 3A and 4, the source electrode SE and the drain electrode DE included in the thin film transistor TFT may have a multi-layer structure.

According to embodiments, each of the source electrode SE and the drain electrode DE may include a first conductive layer 100, a second conductive layer 200 and a third conductive layer 300. The second conductive layer 200 may be disposed on the first conductive layer 100. The third conductive layer 300 may be disposed on the second conductive layer 200. In an embodiment, the conductive layers may respectively form interfaces therebetween.

The arrangement of the electrodes included in the source electrode SE may be substantially the same as or similar to the arrangement of the electrodes included in the drain electrode DE. Therefore, in the following description, the drain electrode DE will be mainly described.

Each of the first conductive layer 100 and the second conductive layer 200 may include a metal. In one embodiment, the first conductive layer 100 may include titanium (Ti), and the second conductive layer 200 may include copper (Cu). However, the present disclosure is not limited thereto, and each of the first conductive layer 100 and the second conductive layer 200 may include various metals.

The third conductive layer 300 may include a metal, an alloy, a metal oxide, or a transparent conductive material. These may be used alone or in combination with each other. In one embodiment, the third conductive layer 300 may include indium tin oxide (ITO), titanium (Ti), titanium oxide (TiOx), zinc indium oxide (ZIO), zinc tin oxide (ZTO), indium gallium zinc oxide (IZGO), zinc indium tin oxide (ZITO), and the like. However, the present disclosure is not limited thereto. In an embodiment, the third conductive layer 300 which is disposed on the second conductive layer 200 may include at least one material selected from a group consisting of a metal material and a metal oxide material. The third conductive layer 300 may include at least one material selected from a group consisting of ITO, Ti, TiOx, ZIO, ZTO, IZGO, and ZITO.

A thickness L3 (e.g., a third thickness) of the third conductive layer 300 may be about 55 nm or more.

When the thickness L3 of the third conductive layer 300 is less than about 55 nm, cracks may occur within the electrode, at an inclined portion of the third conductive layer 300. Accordingly, corrosion may occur in the third conductive layer 300.

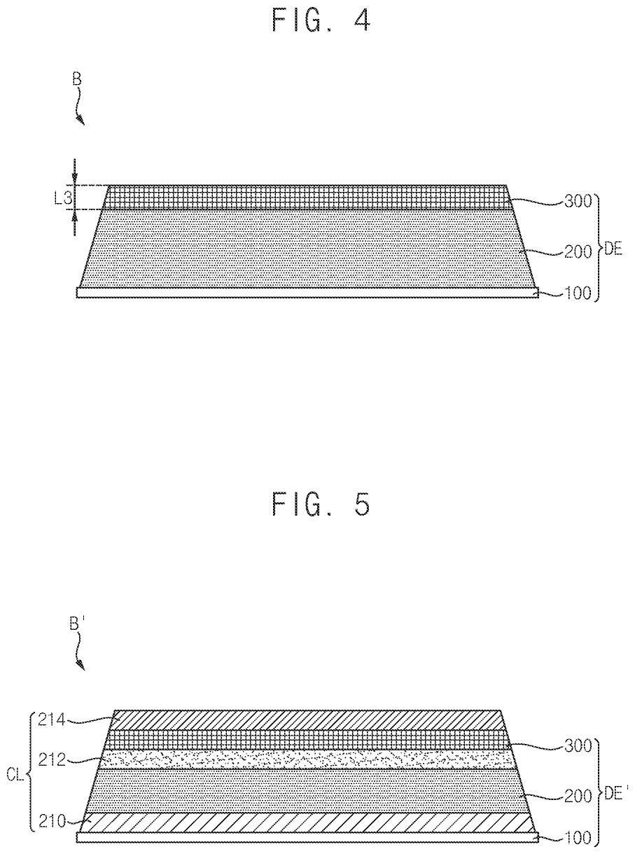

FIG. 5 is an embodiment of area B of FIG. 3A (indicated as B′ in FIG. 5).

Referring to FIGS. 3A and 5, the drain electrode DE′ may further include capping films CL. The capping films CL may include a first capping film 210, a second capping film 212, and a third capping film 214. The first capping film 210 and the second capping film 212 may be respectively disposed above and below the second conductive layer 200. The third capping film 214 may be disposed on the third conductive layer 300. However, the present disclosure is not limited thereto, and any one of the first capping film 210, the second capping film 212, and the third capping film 214 may be omitted.

The capping films CL may be formed by natural oxidation. Specifically, each of the first capping film 210, the second capping film 212, and the third capping film 214 may be formed by the natural oxidation. For example, when the first conductive layer 100, the second conductive layer 200 and/or the third conductive layer 300 meet oxygen, the first capping film 210, the second capping film 212 and/or a third capping film 214 may be formed. That is, each of the conductive layers may include an oxidized portion (e.g., an oxidized thickness portion) which forms an oxidized layer as a capping film within the conductive layer. Optionally, the capping films CL may be artificially formed.

The capping films CL may include metal, metal oxide, and the like. The metal may include titanium (Ti), and the like. The metal oxide may include titanium oxide (TiOx), zinc indium oxide (ZIO), zinc tin oxide (ZTO), indium gallium zinc oxide (IZGO), zinc indium tin oxide (ZITO), and the like. These may be used alone or in combination with each other. In an embodiment, the capping films CL which are disposed on the surface of the second conductive layer 200 which faces the first conductive layer 100 may include at least one material selected from a group consisting of metal material and metal oxide material. The capping films CL may include at least one selected from a group consisting of ITO, Ti, TiOx, ZIO, ZTO, IZGO, and ZITO.

In one embodiment, when the first conductive layer 100 includes titanium (Ti), the first capping film 210 may include the titanium oxide as a first capping oxidized thickness portion by the natural oxidation. When the second conductive layer 200 includes copper (Cu), the second capping film 212 may include the copper oxide as a second capping oxidized thickness portion by the natural oxidation. However, the present disclosure is not limited thereto, and the capping films CL may include various metal oxides depending on the metal material.

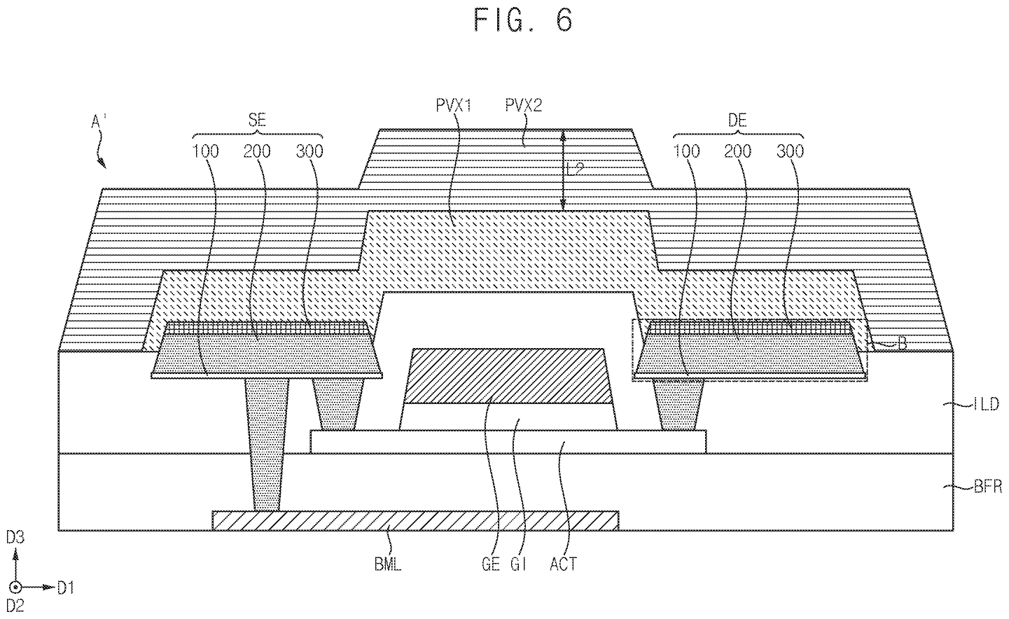

FIG. 6 is an embodiment of area A of FIG. 2 (indicated as A′ in FIG. 6).

The display device 1000 may further include the second passivation layer PVX2. The second passivation layer PVX2 may be disposed on the first passivation layer PVX1, to be closer to the upper substrate 20 than the first passivation layer PVX1. The second passivation layer PVX2 may include an organic material, an inorganic material, and the like. These may be used alone or in combination with each other. In an embodiment, the second passivation layer PVX2 which is disposed on the first passivation layer PVX1 may include at least one material selected from a group consisting of an organic material and an inorganic material. The first passivation layer PVX1 together with or alone without the second passivation layer PVX2 may be referred to as a passivation layer.

The second passivation layer PVX2 may have a single-layer structure or may have a multi-layer structure.

The second passivation layer PVX2 may include silicon oxide (SiOx), silicon nitride (SiNx), silicon oxynitride (SiOxNy), and the like. In one embodiment, the second passivation layer PVX2 may include silicon nitride (SiNx).

In one embodiment, the second passivation layer PVX2 may have a chemical structure including a smaller number of dangling bonds than a chemical structure of the first passivation layer PVX1. When the second passivation layer PVX2 includes the silicon nitride layer SiNx, the dangling bond of the silicon nitride layer SiNx may be defined as a K-center. The dangling bond may mean surplus unbonded electrons present on a surface of a layer, such as a layer which is exposed to another layer and/or at which the layer is bonded/interfaced with the another layer. Additional chemical reactions with moisture, oxygen, and the like may occur by the surplus electrons. That is, as the K-center is reduced, a strong membrane that may block foreign substances such as moisture may be formed.

In one embodiment, a thickness L2 (e.g., a second thickness) of the second passivation layer PVX2 may be about 100 nm or more and about 1000 nm or less.

When the thickness L2 of the second passivation layer PVX2 is less than about 100 nm, the second passivation layer PVX2 may be vulnerable to cracks and the like. Therefore, elements disposed under the second passivation layer PVX2 may not be protected from moisture or foreign substances.

When the thickness L2 of the second passivation layer PVX2 exceeds about 1000 nm, the characteristics of the elements may change, and the change may be disadvantageous to implement the flexible display.

An electrode of the thin film transistor TFT and the a passivation layer may have a stress or strength, such as related to a compressive stress and/or a tensile stress, related to a bonding strength between layers at a bonding interface therebetween, etc. In the display device 1000 according to embodiments of the present disclosure, a difference between an absolute value of the first stress (or strength) of the source electrode SE (or, the drain electrode DE), and an absolute value of the second stress (or strength) of the first passivation layer PVX1 may be about 600 megapascals (MPa) or less. Accordingly, a layer lifting problem at a bonding interface between the source electrode SE and the first passivation layer PVX1, and at a bonding interface between the drain electrode DE and the first passivation layer PVX1, may be improved.

In addition, the display device 1000 may further include the second passivation layer PVX2 in which the K-center is reduced. Accordingly, the display device 1000 may be stored for a long time in the presence of moisture and oxygen. The second passivation layer PVX2 may prevent corrosion of elements or layers within the display device 1000 such as an electrode of the thin film transistor TFT which is closest to a passivation layer, due to moisture or oxygen penetrating.

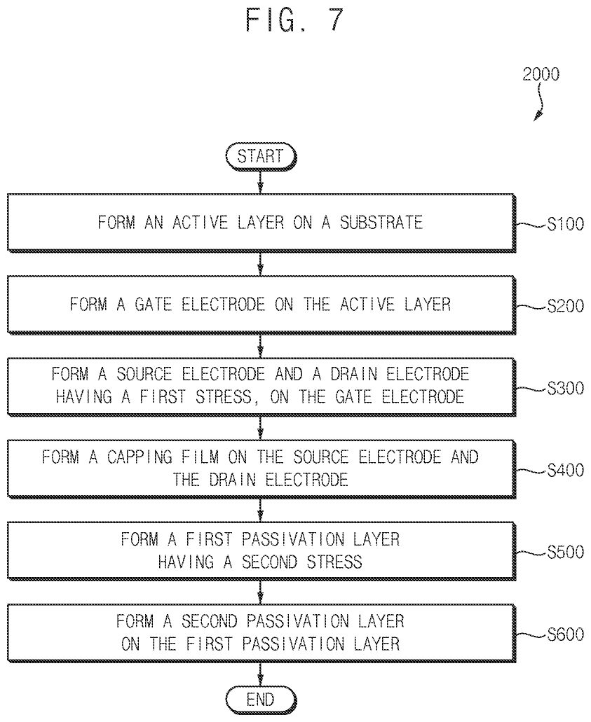

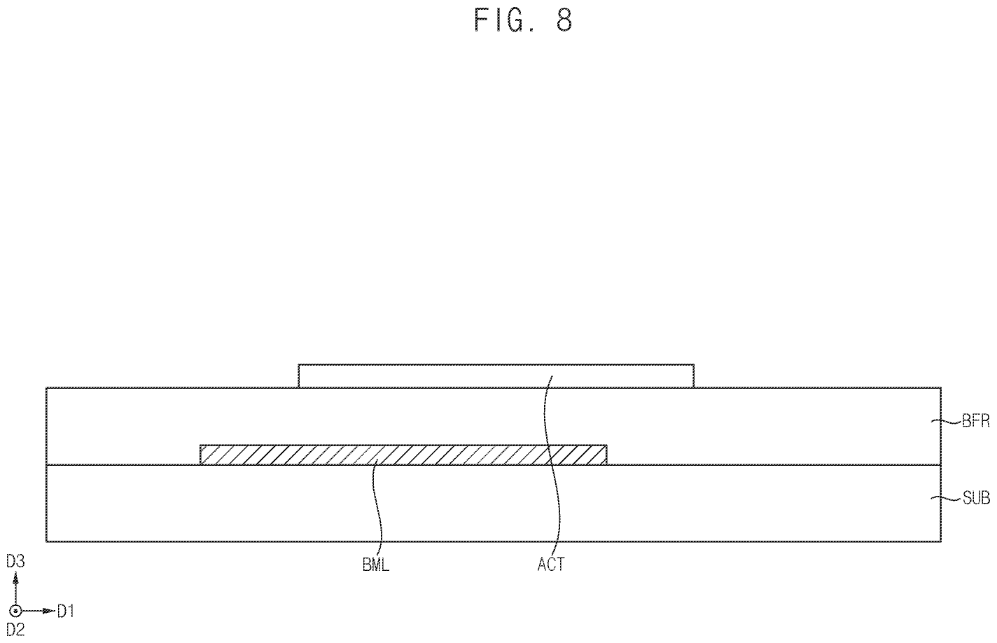

FIG. 7 is a flowchart illustrating a method of manufacturing or providing the display device 1000 according to an embodiment of the present disclosure, and FIGS. 8 to 13 are cross-sectional views illustrating preliminary and intermediate structures of the display device 1000 within the method of FIG. 7.

Referring to FIGS. 7 to 13, the manufacturing method 2000 of the display device 1000 according to embodiments of the present disclosure may include forming (or providing) an active layer ACT on a substrate SUB (S100), forming a gate electrode GE on the active layer ACT (S200), forming a source electrode SE and a drain electrode DE of a thin film transistor TFT on the gate electrode GE (S300), forming a capping film such as including a plurality of capping films on an electrode layer including the source electrode SE and the drain electrode DE (S400), forming a first passivation layer PVX1 of a passivation layer by injecting silane gas (SiH4) and ammonia gas (NH3) onto the source electrode SE and the drain electrode DE (S500), and forming a second passivation layer PVX2 of the passivation layer by adding the silane gas (SiH4), the ammonia gas (NH3) and hydrogen gas (H2) onto first passivation layer PVX1 (S600).

The source electrode SE and the drain electrode DE may have a first stress. The first stress may be between about 0 MPa and about 200 MPa or less.

The first passivation layer PVX1 may have a second stress. A difference between the absolute value of the second stress and the absolute value of the first stress may be about 600 MPa or less. Hereinafter, processes will be described in detail, but overlapping descriptions with those of the display device 1000 described above with reference to FIGS. 1 to 6 will be omitted or simplified.

Referring to FIG. 8, the active layer ACT may be formed on the substrate SUB (S100). Specifically, the active layer ACT may be formed of or include pure amorphous silicon, on a plastic substrate SUB (e.g., a base substrate).

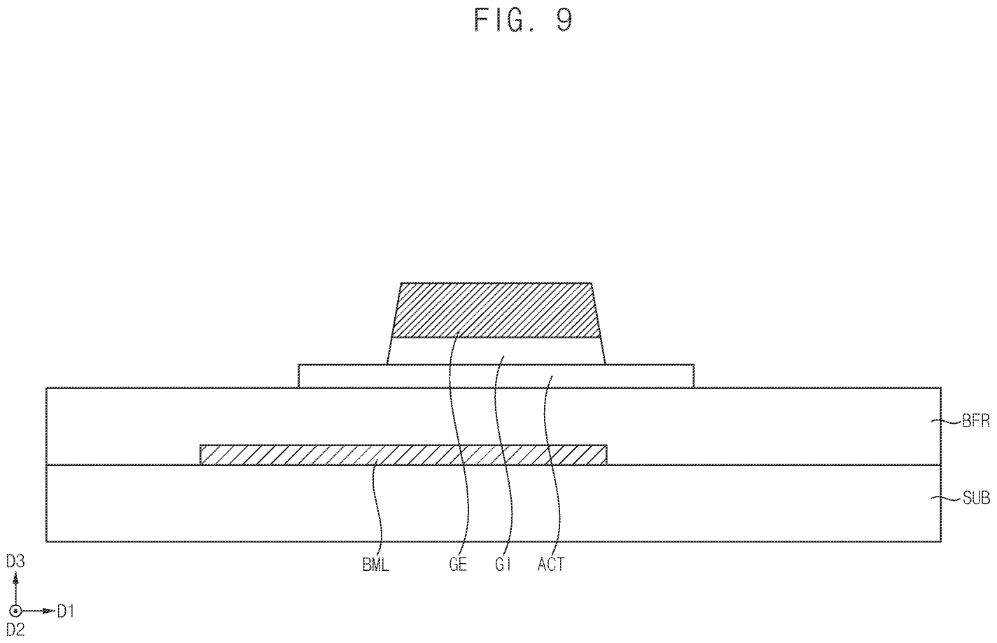

Referring to FIG. 9, the gate electrode GE of a first electrode layer, may be formed on the active layer ACT (S200). Specifically, the gate electrode GE may be formed of a conductive material.

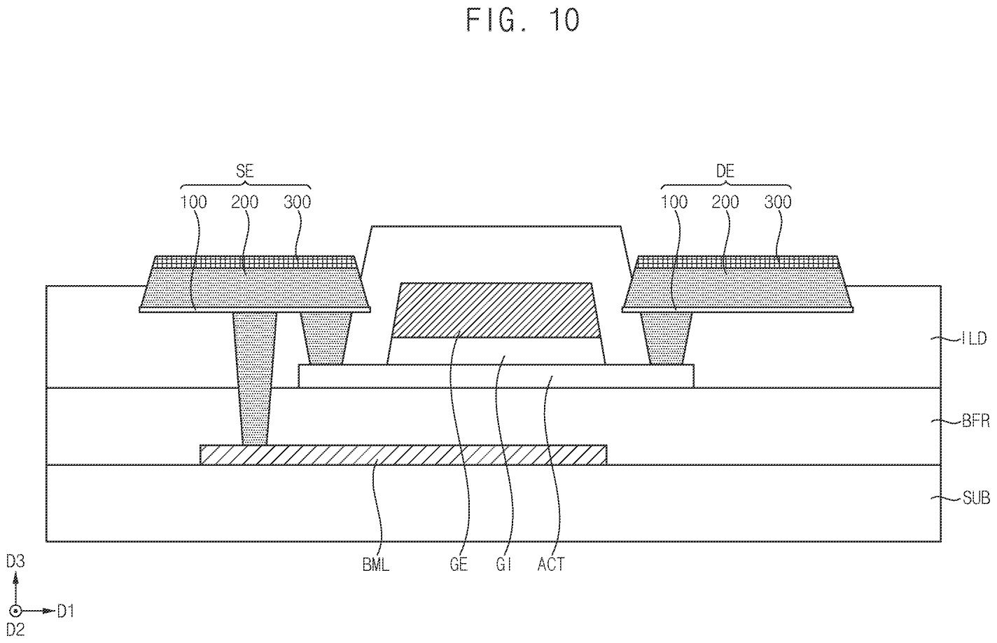

Referring to FIG. 10, the source electrode SE and the drain electrode DE of a second electrode layer may be formed on the gate electrode GE (S300). The source electrode SE and the drain electrode DE may be formed by stacking the first conductive layer 100, the second conductive layer 200, and the third conductive layer 300 sequentially along the third direction D3, from the substrate SUB. That is, the first conductive layer 100, the second conductive layer 200, and the third conductive layer 300 among conductive layers of the second electrode layer may be in order along the thickness direction.

The source electrode SE and the drain electrode DE may be in a same layer as each other. Patterns within a first conductive material layer, a second conductive material layer and a third conductive material layer which respectively provide the first conductive layer 100, the second conductive layer 200, and the third conductive layer 300, may be in a same layer as each other. As being in a same layer, elements may be formed in a same process and/or as including a same material as each other, elements may be respective portions of a same material layer, elements may be on a same layer by forming an interface with a same underlying or overlying layer, etc., without being limited thereto.

The source electrode SE and the drain electrode DE may have the first stress. In detail, the third conductive layer 300 as an uppermost layer of the second electrode layer, may have the first stress.

The first stress may exceed 0 MPa and be less than or equal to about 200 MPa. An amorphous structure of indium tin oxide (ITO) may have compressive stress of about −300 MPa. During the continuous layer formation process of indium tin oxide (ITO) by a sputtering method, the amorphous structure may be changed into a crystalline structure. The crystalline structure of indium tin oxide (ITO) may have a different stress from that of the amorphous structure of indium tin oxide (ITO). For example, the stress of the crystalline structure of indium tin oxide (ITO) may exceed 0 MPa. Specifically, the stress of the amorphous structure (e.g., an original structure or preliminary structure) of indium tin oxide (ITO) may be about −300 MPa, but the stress of the crystalline structure (e.g., a processed structure or formed structure) of indium tin oxide (ITO) may be about 200 MPa.

In order to improve adhesion of the second electrode layer (or the thin film transistor TFT) with the passivation layer at the first passivation layer PVX1, contaminants may be removed from the second electrode layer by hydrogen plasma treatment performed on or at the third conductive layer 300.

Optionally, in order to improve adhesion of the second electrode layer with the first passivation layer PVX1, heat treatment may be performed on the third conductive layer 300. At this time, the heat treatment may be performed at a temperature of about 200 degrees or more. Residual stress within the formed structure of the second electrode layer may be relieved by the heat treatment.

Optionally, in order to improve adhesion of the second electrode layer with the first passivation layer PVX1, an interfacial silane-based coupling agent may be introduced into the third conductive layer 300. The interfacial silane-based coupling agent may include an amphoteric material to bond a hydrophilic and hydrophobic interface when the interface of a material is heterogeneous.

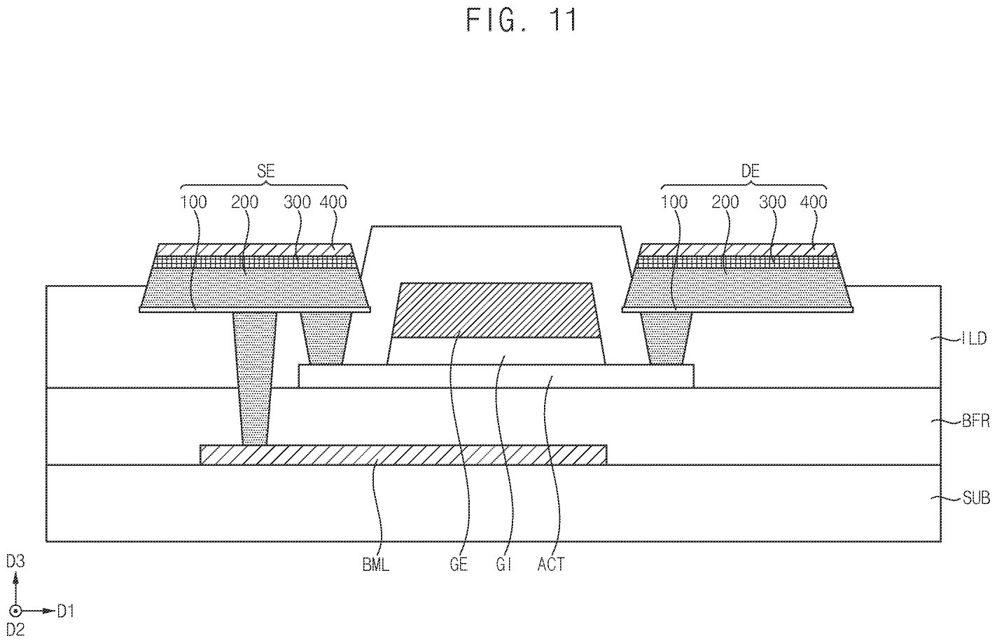

Referring to FIG. 11, a capping film 400 may be formed on the source electrode SE and the drain electrode DE (S400). Although the capping film 400 is shown on the third conductive layer 300, the present disclosure is not limited thereto. The capping film 400 may be formed in place of the third conductive layer 300. Referring to FIG. 5, for example, the capping film 400 may be formed below the third conductive layer 300. That is, the capping film 400 may be formed above and/or below the third conductive layer 300 along the third direction D3. Optionally, the capping films 400 may be formed above and/or below the second conductive layer 200.

In one embodiment, the capping film 400 including a metal may be formed on the source electrode SE and the drain electrode DE. For example, the capping film 400 including titanium (Ti) or the like may be formed on the source electrode SE and the drain electrode DE.

In an embodiment, the capping film 400 including a metal oxide may be formed on the source electrode SE and the drain electrode DE. For example, the capping film 400 including titanium oxides (TiOx) or the like may be formed on the source electrode SE and the drain electrode DE.

However, the present disclosure is not limited thereto, and the process of providing the capping film 400 (S400) may be omitted.

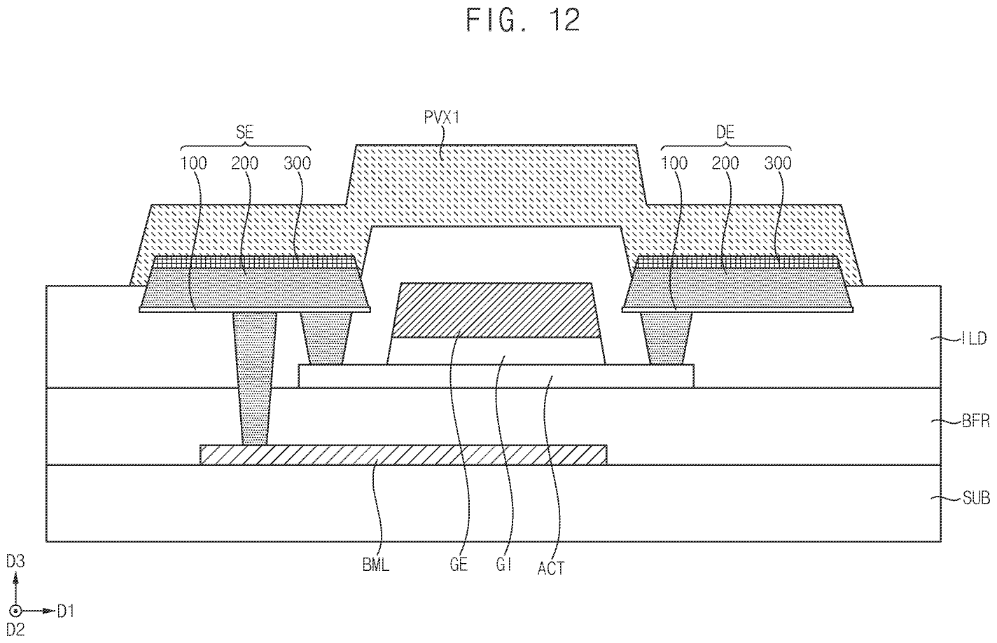

Referring to FIG. 12, the first passivation layer PVX1 may be formed on the source electrode SE and the drain electrode DE (S500). In detail, the first passivation layer PVX1 may be formed on an uppermost layer of the second electrode layer, such as on the third conductive layer 300. In an embodiment where the capping film 400 is formed on the third conductive layer 300, the first passivation layer PVX1 may be formed on the capping film 400.

The first passivation layer PVX1 may be patterned as shown in FIG. 3A, or the first passivation layer PVX1 may be formed on the entire surface as shown in FIG. 3B. Below, the case where the first passivation layer PVX1 is patterned as shown in FIG. 3A has been described, but the present disclosure is not limited thereto. At the interface where different layers of the stacked structure are in contact with each other, a layer lifting problem may occur easily. In order to improve the problem, a roughness of the first passivation layer PVX1 disposed on the source electrode SE and the drain electrode DE, may have a small value.

The first passivation layer PVX1 may be formed of the silicon material, the metal oxide, and the like. In one embodiment, the first passivation layer PVX1 may be formed of the silicon nitride layer (SiNx). The silicon nitride layer (SiNx) may be formed by introducing the silane gas (SiH4), the ammonia gas (NH3), and the nitrogen gas (N2) into a chamber and decomposing the gases in a plasma state to provide the first passivation layer PVX1. Reactive gases may be used alone or in combination with each other.

The first passivation layer PVX1 may be deposited by using any one of chemical vapor deposition (CVD), sputtering (SPT), atomic layer deposition (ALD), and sol-gel.

In one embodiment, the thickness L1 of the first passivation layer PVX1 may be about 200 nm or more and about 700 nm or less. A detailed description of the numerical range of the thickness L1 of the first passivation layer PVX1 is as described above with reference to FIG. 4.

The first passivation layer PVX1 may have the second stress. In one embodiment, the second stress of the first passivation layer PVX1 may be the compressive stress of about −400 MPa or more and less than about 0 MPa. In an embodiment, the second stress of the first passivation layer PVX1 may be the compressive stress of about −400 MPa or more and less than about −200 MPa.

When the second stress of the first passivation layer PVX1 is less than about −400 MPa, a layer lifting may occur between the source electrode SE (or the drain electrode DE) and the first passivation layer PVX1.

When the second stress of the first passivation layer PVX1 exceeds about 0 MPa, negative shift of a threshold voltage may occur. Accordingly, the characteristics of the elements disposed under the first passivation layer PVX1 may change and be unusable.

As described above with reference to FIG. 10, the source electrode SE (or the drain electrode DE) may have the compressive stress, and the first passivation layer PVX1 may have a tensile stress. In detail, the stress of the indium tin oxide (ITO) of the crystalline structure within the second electrode layer may be about 200 MPa, and the second stress of the first passivation layer PVX1 may have a comparative stress of about −750 MPa. In other words, the difference between the absolute value of the comparative second stress of the first passivation layer PVX1 and the absolute value of the first stress of the source electrode SE (or the drain electrode DE) may exceed about 900 MPa. That is, the source electrode SE (or the drain electrode DE) and the first passivation layer PVX1 have stresses in opposite directions from each other. The source electrode SE (or the drain electrode DE) and the first passivation layer PVX1 may be biased or bent in opposite directions to each other by the stresses of the respective patterns. Accordingly, a layer lifting problem may occur at the bonding interface between the first passivation layer PVX1 and the source electrode SE (or the drain electrode DE). This is called stress mismatching.

On the other hand, another problem may occur when the first passivation layer PVX1 is formed to have the tensile stress in order to solve the stress mismatching. When the second stress of the first passivation layer PVX1 is about 0 MPa or more, a hydrogen emission amount may increase about 11 times compared to when the second stress of the first passivation layer PVX1 is about −750 MPa. As the hydrogen emission amount increases by about 11 times, a threshold voltage change of the elements disposed under the first passivation layer PVX1 may occur. Accordingly, the characteristics of the elements may be changed so that the elements may not be used.

However, in the case of the first passivation layer PVX1 included in the display device 1000 according to the embodiments, the second stress may be about −400 MPa or more and less than about 0 MPa. Accordingly, a difference in the hydrogen emission amount for the first passivation layer PVX1 having the second stress of about −400 MPa or more and less than 0 MPa, as compared to the hydrogen emission amount of the first passivation layer PVX1 having the stress of about −750 MPa. That is, there may be no change in characteristics of the elements disposed under the first passivation layer PVX1 since the hydrogen emission amount is minimized by one or more of the first passivation layer PVX1 according to the embodiments.

In summary, the layer lifting due to stress mismatching may be prevented by reducing the difference between the absolute value of the first stress and the second stress. However, when the second stress has a tensile stress, the characteristics of the elements may be changed so that the elements may not be used. Accordingly, the second stress of the first passivation layer PVX1 may be formed to have the compressive stress. The difference between the absolute value of the second (compressive) stress and the absolute value of the first stress may be about 600 MPa or less, and the second stress may be the compressive stress of about −400 MPa or more and less than 0 MPa.

As described above, the layer lifting problem due to the stress mismatching may be improved by adjusting the second stress value of the first passivation layer PVX1. Hereinafter, characteristics capable of improving the layer lifting problem in addition to the second stress will be described.

The thickness L1 of the first passivation layer PVX1 may be about 200 nm and or more and about 700 nm or less. A layer density may be about 2.2 grams per cubic centimeter (g/cm³) or more and about 2.5 g/cm³ or less. A silicon-to-nitrogen ratio (N/Si ratio) may be about 1.09 or more and about 1.2 or less. A refractive index may be about 1.8 or more and about 1.9 or less. The K-center may be about 4.0×10¹⁸ spins per cubic centimeter (spins/cm³) or more and about 8.8×10¹⁸ spins/cm³ or less. Hydrogen in the layer may be about 1.0×10²² atoms per cubic centimeter (atoms/cm³) or more and about 2.0×10²² atoms/cm³ or less. The hydrogen emission amount may be about 6.0×10²⁰ molecules per cubic centimeter (molec./cm³) or more and about 9.8×10²² molec./cm³ or less. The roughness of the first passivation layer PVX1 formed on the source electrode SE and the drain electrode DE may be about 0.3 nm or more and about 1.1 nm or less.

As the above characteristics are satisfied, the layer lifting problem at the bonding interface between the first passivation layer PVX1 and the source electrode SE (or the drain electrode DE) may be further improved. However, the manufacturing method 2000 of the display device according to embodiments of the present disclosure is not limited to the above materials, procedures, and methods.

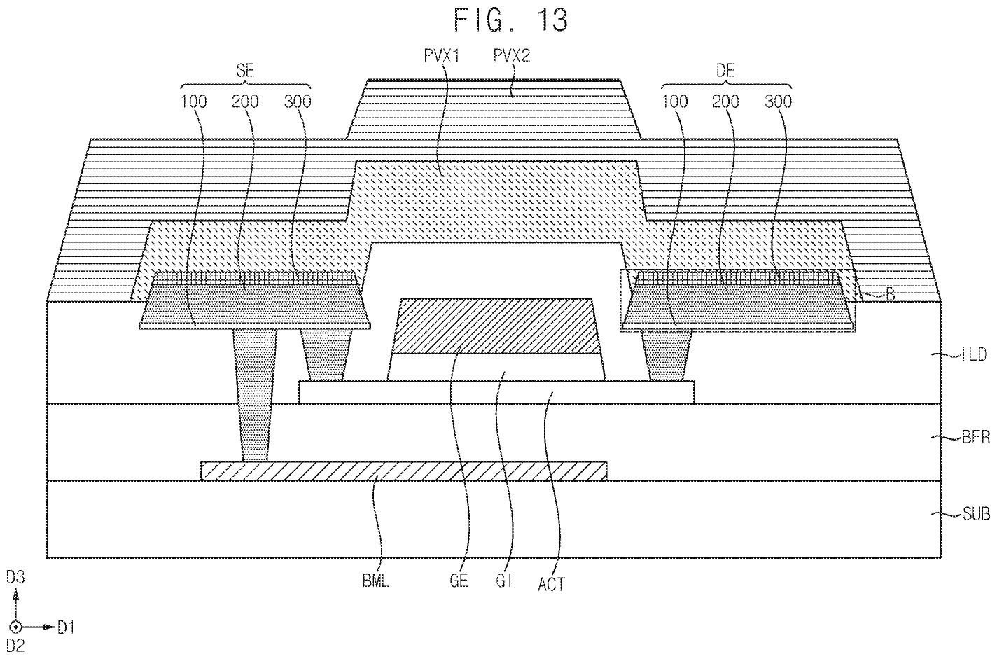

Referring to FIG. 13, the manufacturing method 2000 of the display device 1000 may further include forming the second passivation layer PVX2 by adding hydrogen gas (H2) to the silane gas (SiH4), the ammonia gas (NH3) and the nitrogen gas (N2) (S600), after forming the first passivation layer PVX1 (S500). In an embodiment, for example, the providing of the second passivation layer PVX2 may include after the forming of the first passivation layer PVX1, introducing the hydrogen gas (H2), the silane gas (SiH4), the ammonia gas (NH3), and the nitrogen gas (N2) into a chamber and decomposing the gases in a plasma state to provide the second passivation layer PVX2. Reactive gases may be used alone or in combination with each other.

The second passivation layer PVX2 may be formed on the first passivation layer PVX1. In one embodiment, each of the first passivation layer PVX1 and the second passivation layer PVX2 may include a silicon nitride film (SiNx). In this case, content of nitrogen compared to silicon of the second passivation layer PVX2 may be smaller than the content of nitrogen compared to silicon of the first passivation layer PVX1.

In an embodiment, the thickness L2 of the second passivation layer may be about 100 nm or more and about 1000 nm or less.

The second passivation layer PVX2 may be deposited by using any one of chemical vapor deposition (CVD), sputtering (SPT), atomic layer deposition (ALD), and sol-gel.

In one embodiment, the second passivation layer PVX2 may have a smaller number of dangling bonds than the first passivation layer PVX1. That is, the K-center of the second passivation layer PVX2 significantly smaller than the K-center of the first passivation layer PVX1. Accordingly, the second passivation layer PVX2 may effectively protect the elements from penetration of moisture and oxygen.

For example, the second passivation layer PVX2 may be formed of silane gas (SiH4), ammonia gas (NH3), nitrogen gas (N2), and the like. The reactive gases may be used alone or in combination with each other. By further adding hydrogen gas to the reaction gases, the number of dangling bonds included in the silicon nitride layer (SiNx) may be reduced by about 27%. That is, by further adding hydrogen gas to the reaction gases, the second passivation layer PVX2 may form a strong membrane.

However, the manufacturing method 2000 of the display device 1000 according to embodiments of the present disclosure is not limited to the above materials, procedures, and methods.

As a result of applying one or more the manufacturing method 2000 of the display device 1000 according to the embodiments of the present disclosure, the layer lifting problem has been improved.

A comparative mother substrate included a first passivation layer PVX1 having the compressive stress of about 750 MPa. When the manufacturing method of the display device including the first passivation layer PVX1 having the compressive stress of about 750 MPa was applied, the layer lifting problem occurred at about 138 locations along the comparative mother substrate.

A mother substrate according to an embodiment included the compressive stress of about −400 MPa or more and less than about 0 MPa. On the other hand, when the manufacturing method 2000 of the display device 1000 according to the embodiments of the present disclosure is applied, the layer lifting problem occurs at about one location along the mother substrate according to the embodiment.

That is, the display device 1000 according to embodiments of the present disclosure may include the first passivation layer PVX1 (with or without the second passivation layer PVX2) to effectively prevent occurrence of reliability bright spots due to penetration of oxygen and moisture.

The display device 1000 and the method of manufacturing (or providing) the same according to the embodiments may be applied to a display device 1000 included in high-resolution smartphones, mobile phones, smart pads, smart watches, tablet personal computers (PCs), vehicle navigation systems, televisions, computer monitors, notebooks, or the like.

Although the methods and the systems according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a thin film transistor including:
an active layer;
a gate electrode on the active layer; and
an electrode layer having a first stress, the electrode layer including a source electrode and a drain electrode;
a light emission layer facing the thin film transistor; and
a first passivation layer between the thin film transistor and the light emission layer and covering the thin film transistor, the first passivation layer having a second stress,
wherein a difference between an absolute value of the first stress and an absolute value of the second stress is about 600 megapascals or less.

2. The display device of claim 1, wherein a roughness of the first passivation layer is about 0.3 nanometer or more and about 1.1 nanometers or less.

3. The display device of claim 1, wherein the second stress of the first passivation layer is a compressive stress of about −400 megapascals or more and less than about 0 megapascals.

4. The display device of claim 1, wherein a thickness of the first passivation layer is about 200 nanometers or more and about 700 nanometers or less.

5. The display device of claim 1, further comprising:
a second passivation layer including an organic material or an inorganic material, and
the first passivation layer between the thin film transistor and the second passivation layer.

6. The display device of claim 5, wherein
each of the first passivation layer and the second passivation layer has surplus unbonded electrons on a surface to define a number of dangling bonds, and
the number of dangling bonds of the second passivation layer is smaller than the number of dangling bonds of the first passivation layer.

7. The display device of claim 5, wherein
each of the first passivation layer and the second passivation layer includes silicon nitride or silicon oxynitride,
each of the silicon nitride and the silicon oxynitride has a content of nitrogen relative to silicon, and
the content of nitrogen relative to silicon of the first passivation layer is greater than the content of nitrogen relative to silicon of the second passivation layer.

8. The display device of claim 5, wherein a thickness of the second passivation layer is about 100 nanometers or more and about 1000 nanometers or less.

9. The display device of claim 1, wherein within the electrode layer of the thin film transistor, each of the source electrode and the drain electrode includes in order toward the first passivation layer:
a first conductive layer;
a second conductive layer; and
a third conductive layer including a metal or a metal oxide.

10. The display device of claim 9, wherein
the first conductive layer includes Ti, and
the second conductive layer includes Cu.

11. The display device of claim 10, wherein the third conductive layer includes at least one among indium tin oxide, titanium, titanium oxide, zinc indium oxide, zinc tin oxide, indium gallium zinc oxide and zinc indium tin oxide.

12. The display device of claim 11, wherein the first stress is defined by the third conductive layer and is greater than about 0 MPa and is about 200 MPa or less.

13. The display device of claim 11, wherein each of the source electrode and the drain electrode further includes:
a capping film including a metal or a metal oxide, and
the capping film between the first conductive layer and the second conductive layer.

14. The display device of claim 13, wherein the capping film includes at least one among indium tin oxide, titanium, titanium oxide, zinc indium oxide, zinc tin oxide, indium gallium zinc oxide and zinc indium tin oxide.

15. The display device of claim 11, wherein each of the source electrode and the drain electrode further includes:
a capping film including a metal or a metal oxide, and
the capping film between the second conductive layer and the third conductive layer.

16. The display device of claim 15, wherein the capping film includes at least one among indium tin oxide, titanium, titanium oxide, zinc indium oxide, zinc tin oxide, indium gallium zinc oxide and zinc indium tin oxide.

17. The display device of claim 1, further comprising:
an impact-resistance layer between the first passivation layer and the light emission layer; and
a color filter layer on the light emission layer.

18. A method of providing a display device, the method comprising:
providing a thin film transistor including:
an active layer,
a gate electrode on the active layer,
an electrode layer having a first stress greater than about 0 MPa and less than about 200 MPa, and
the electrode layer including a source electrode and a drain electrode; and
providing a first passivation layer on the thin film transistor, the first passivation layer having a second stress,
wherein the providing of the first passivation layer includes:
injecting silane gas and ammonia gas, on the source electrode and the drain electrode; and
defining a difference between an absolute value of the first stress and an absolute value of the second stress of about 600 megapascals or less.

19. The method of claim 18, further comprising after the providing of the first passivation layer, providing a second passivation layer on the first passivation layer,
wherein the providing of the second passivation layer includes injecting hydrogen gas in addition to the silane gas and the ammonia gas, on the source electrode and the drain electrode.

20. The method of claim 18, further comprising after the providing of the source electrode and the drain electrode, providing a capping film including a metal or a metal oxide, on the source electrode and the drain electrode.
